(19) United States
(12) Patent Application Publication
(10) Pub. No.: US 2012/0204922 A1
(43) Pub. Date: Aug. 16, 2012

(54) THERMOELECTRIC ROOFING APPARATUS AND METHOD FOR GENERATING ELECTRICITY

(75) Inventors: Luis M. Ortiz, Albuquerque, NM (US); Kermit D. Lopez, Albuquerque, NM (US)

(73) Assignee: Mesa Digital, LLC.

(21) Appl. No.: 13/028,375

(22) Filed: Feb. 16, 2011

(51) Int. Cl. H01L 35/30; H01L 21/20

(52) U.S. Cl. 136/206; 438/54; 257/E21.09

(57) ABSTRACT

A thermoelectric roofing apparatus and method for generating electricity as a byproduct of heat exchange. A thermoelectric coating can be applied on a heat exchanger material (e.g., a roofing material, a shingle, etc.) located on a budding utilizing a thermoelectric coating process (e.g., spray-on coating) in order to capture waste heat from a heat source and generate an electrical energy. The thermoelectric coating can be a semiconductor material that can be applied to the heat exchanger material in a printed circuit format. The charge carriers with respect to the semiconductor material can be excited when heat flows through the thermoelectric coating which can be harvested to generate the electrical power. Electrical conductors can be attached to the thermoelectric coating to transmit the electrical energy generated as a byproduct of heat exchange.

### TECHNICAL FIELD

Embodiments are generally related to thermoelectric power generation methods and systems. Embodiments are additionally related to heat exchangers. Embodiments are further related to thermoelectric roofing materials.

### BACKGROUND OF THE INVENTION

Electrical energy can be easily transmitted to remote locations via an electrical conductor and without the requirement of mechanical transport. Electrical energy may be employed for heating, lighting, the generation of mechanical motion via a motor and an actuator, and also to power electronic and other devices. In less developed parts of the world, however, the supply of electricity is unreliable and completely unavailable in remote locations. As a result, there exists a need for a simple and cost efficient generation of electrical power on a localized basis.

The thermoelectric effect is the direct conversion of temperature differences to electric voltage and vice versa. A thermoelectric device includes a thermoelement that creates a voltage when there is a different temperature on each side (Seebeck effect). Conversely, when a voltage is applied to the thermoelectric device a temperature difference (Peltier effect) is created. Such thermoelements may be configured utilizing a conductor such as bismuth and/or antimony, whereas higher efficiency thermoelectrics can be built utilizing a heavily doped semiconductor.

One example of a thermoelectric approach to power generation is disclosed in U.S. Patent Publication No. 2010/0154855 entitled “Thin Walled Thermoelectric Devices and Methods for Production Thereof,” which published on Jun. 24, 2010 and is incorporated herein by reference in its entirety. Another example of a thermoelectric approach for generating electricity is disclosed in U.S. Pat. No. 6,127,766, which issued to R. Michael Roidt on Oct. 3, 2000, and which is als incorporated by reference in its entirety.

In general, thermoelectric generation takes place when a temperature difference is applied to the thermoelements, causing mobile charge carriers, either electrons or holes, to migrate from hot to cold. The resulting separation of charge creates an electric potential known as the Seebeck voltage. A Seebeck coefficient for a material may be positive or negative depending upon the type of majority charge carrier.

The majority of prior art thermoelectric power generation systems appear suitable for specialized applications and are not harnessed to generate electric power for use on a localized basis. Additionally, in remote environments, production of the thermoelectric power from such conventional means can be very difficult.

Based on foregoing, it is believed that a need exists for an improved thermoelectric roofing apparatus and method for generating electricity as a byproduct of heat exchange, as described in greater detail herein.

### BRIEF SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings, and abstract as a whole.

It is, therefore, one aspect of the disclosed embodiments to provide an improved thermoelectric power generation system and method.

It is another aspect of the disclosed embodiments to provide for an improved thermoelectric roofing material for generating electricity on a roof structure as a byproduct of heat exchange.

The aforementioned aspects and other objectives and advantages can now be achieved as described herein. A thermoelectric roofing apparatus and method for generating electricity as a byproduct of heat exchange is disclosed herein. A thermoelectric coating can be applied on a heat exchanger material (e.g., a roofing material, a shingle, etc.) located on a building (e.g., home or business) utilizing a thermoelectric coating process (e.g., spray-on coating) in order to capture waste heat from a heat source and generate an electrical energy. The thermoelectric coating can be a semiconductor material that can be applied to the heat exchanger material in a printed circuit format. The charge carriers with respect to the semiconductor material can be excited when heat flows through the thermoelectric coating which can be harvested to generate the electrical power. Electrical conductors can be attached to the thermoelectric coating to transmit the electrical energy generated as a byproduct of heat exchange.

The thermoelectric coating acts as a thermal collector in order to capture heat from the heat source. The spray-on thermoelectric coating can be applied for improving the thermoelectric properties. The semiconductor material includes one or more p type thermoelements and n type thermoelements. The p type thermoelements and n type thermoelements can be connected in electrical series and in thermal parallel. The thermoelectric generation takes place when a temperature difference is applied to the thermo elements, causing mobile charge carriers, either electrons or holes, to migrate from hot to cold resulting in an electric potential known as the Seebeck voltage, Energy losses associated with the active thermoelectric element due to joule heating can be minimized as the thermo elements have a high electrical conductivity.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a block diagram of a thermoelectric roofing apparatus for generating electricity as a byproduct of heat exchange, in accordance with the disclosed embodiments;

FIG. 2 illustrates a perspective view of a roof structure configured with a thermoelectric roofing material, in accordance with the disclosed embodiments;

FIG. 3 illustrates a circuit diagram of a two-element thermoelectric generation unit, in accordance with the disclosed embodiments; and

FIG. 4 illustrates a high level flow chart of operation illustrating logical operational steps of a method for generating electricity on a roof structure as a byproduct of heat exchange, in accordance with the disclosed embodiments.

### DETAILED DESCRIPTION

The particular values and configurations discussed in these non-limiting examples can be varied and are cited merely to illustrate at least one embodiment and are not intended to limit the scope thereof.

The embodiments now will be described more fully hereinafter with reference to the accompanying drawings, in which illustrative embodiments of the invention are shown. The embodiments disclosed herein can be embodied in many different forms and should not be construed as limited to the embodiments set forth herein; rather, these embodiments are provided so that this disclosure will be thorough and complete and will fully convey the scope of the invention to those skilled in the art. Like numbers refer to like elements throughout. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

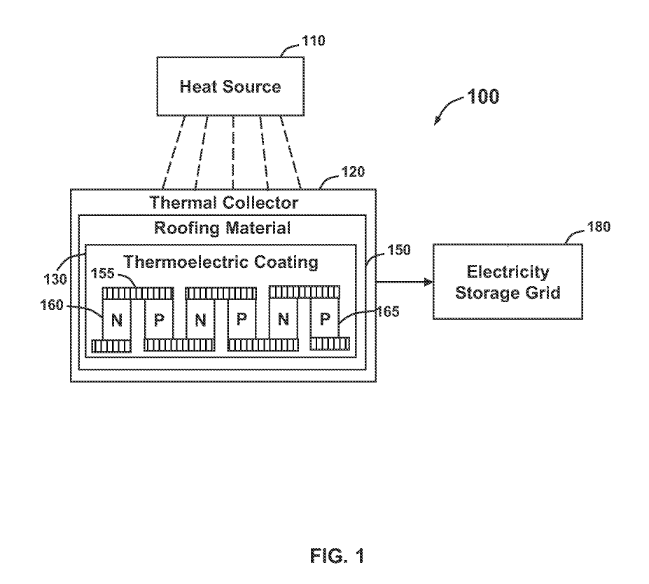

FIG. 1 illustrates a block diagram of a thermoelectric roofing apparatus 100 having a thermoelectric coating 130 for generating electricity form a heat source 110, in accordance with the disclosed embodiments. The thermoelectric coating 130 can be applied to a roofing material 150 utilizing a thermoelectric coating process, which allows the roofing material 150 to capture waste heat from the heat source 110 and generate electrical energy. In a preferred embodiment, the roofing material 150 (e.g., roofing shingles) is located on a roof of a building and exposed to the energy of the sun. The roofing material 150 transfers heat energy from one material to a second material without mixing the materials. The thermoelectric coating 130 acts as a thermal collector 120 in order to capture heat from the heat source 110. The thermal collector 120 can be designed to collect heat by absorbing heat from the heat source 110 such as, for example, solar energy. The thermal collector 120 can convert the heat energy received from the heat source 110 into a more usable or storable form such as electrical energy. The thermal collector 120 can be typically employed for supplemental space heating in residential and commercial buildings.

The roofing material 150 can be, for example, a heat exchanger (e.g., a roofing shingle), depending upon design considerations. The thermoelectric coating 130 can be a semiconductor material that can be applied to the roofing material 150 in a printed circuit format. The spray-on thermoelectric coating 130 can be applied for improving the thermoelectric properties. The spray-on thermoelectric coating 130 can deposit one solid material on top of another by ejecting a high velocity heated powder onto a target surface so that the powder fuses into a solid with a good mechanical and thermal connection.

The thermoelectric apparatus 100 includes one or more p type thermoelements 165 and one or more n type thermoelements 160. The p type thermoelements 165 and the n type thermoelements 160 can be connected in electrical series and in thermal parallel via one or more conductors 155. The n-type thermoelectric material 160 is a metal, semimetal or semiconductor that can be employed for thermoelectric applications. The n-type doped semiconductor thermoelectric material 160 possesses the property to convert a portion of the heat flux (heat energy flowing through it) into electricity, with the majority electrical carrier being electrons.

The p-type thermoelectric material 165 is a metal, semimetal or semiconductor that can be utilized for thermoelectric applications. The p-type doped semiconductor thermoelectric material 165 possesses the property to convert a portion of the heat flux into electricity with the majority electrical carrier being holes. The charge carriers associated with the thermoelements 160 and 165 can be excited when heat flows through the thermoelectric coating 130 which can be harvested to generate the electrical power. Electrical conductors can be attached to the thermoelectric coating 130 to transmit the electrical energy generated as a byproduct of heat exchange to, for example, an electrical grid 180. Note that as utilized herein the term “electrical grid” can refer to a large scale electrical grid for transferring electricity to multiple homes, buildings, and other facilities, or may refer simply to the “electrical grid” within a single home, building or other facility.

Thermoelectric generation takes place when a temperature difference is applied to the thermoelements 160 and 165, causing mobile charge carriers, either electrons or holes, to migrate from hot to cold resulting in an electric potential known as the Seebeck voltage. The heat source 110 can be, for example, solar energy, transferring its energy to the thermoelectric apparatus 100 by conduction. In some embodiments, heat source 110 can transfer energy to the thermoelectric apparatus 100 exclusively through radiative heat transfer. Energy losses associated with the active thermoelectric elements 160 and 165 due to joule heating can be minimized due to their high electrical conductivity. Furthermore, the electrical grid 180 can be disposed to collect the electrical energy from the thermoelectric apparatus 100 before the electrical energy is transmitted.

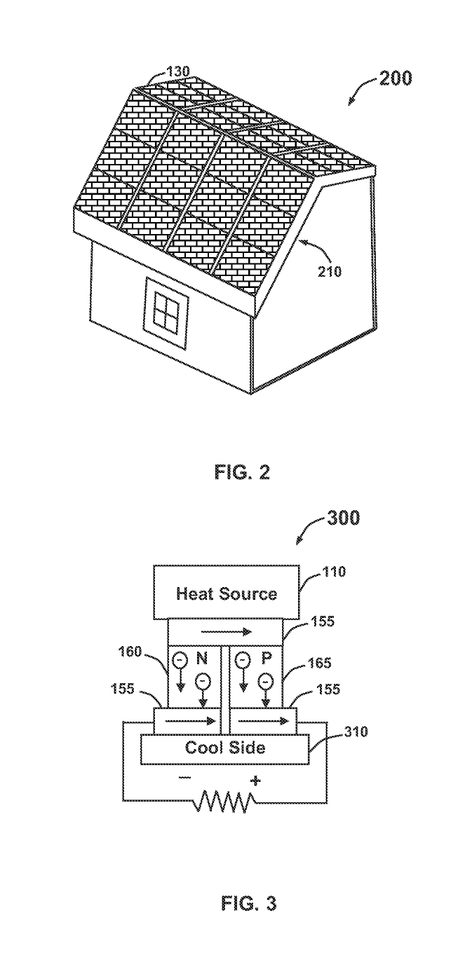

FIG. 2 illustrates a perspective view of a roof structure 200 configured with the thermoelectric roofing material 130, in accordance with the disclosed embodiments. Note that in FIGS. 1-4, identical or similar blocks are generally indicated by identical reference numerals. The thermoelectric coating 130 can be applied on a top surface 210 of the roof structure 200 on a home or a business or building in order to convert waste heat energy into electric potential. The thermoelectric apparatus 100 converts the heat captured by the thermoelectric coating 130 into electricity utilizing the principle of thermoelectric effect. Furthermore, the electrical grid 180 can be disposed to collect the electrical energy from one or more thermoelectric apparatus 100 before the electrical energy is transmitted. The DC voltage generated from the thermoelectric coating 130 can be transformed into an AC voltage suitable for delivery to the electrical grid 180 by a DC to AC converter (not shown). The electrical grid 180 is an interconnected network for delivering electricity from the thermoelectric device 100 to an electric power source.

FIG. 3 illustrates a circuit diagram of the two-element thermoelectric generation unit 300, in accordance with the disclosed embodiments. In the thermoelectric generation unit 300 depicted in FIG. 3, the heat flows from the heat source 110 to a cool side 310 so that the charge carriers flow in the direction of the heat flow, which results in an electrical charge. The heat source 110 is the reservoir having a higher temperature while the cool side 310 has a lower temperature. The direction of heat energy flow is from the heat source 110 to the cool side 310. The electrons in the n type thermoelement 160 can move opposite the direction of current and holes in the p type thermoelement 165 can move in the direction of current, both removing heat from one side of the device.

The generated electrical charge can then be employed to power a load, thus converting the thermal energy into electrical energy. The electrical grid 180 can be a resistive load such as a heater or an incandescent light, or it can be an electronic converter unit that converts the electrical power generated by the thermoelectric generation unit 150 into a different form. Note that the embodiments discussed herein should not be construed in any limited sense. It can be appreciated that such embodiments reveal details of the structure of a preferred form necessary for a better understanding of the invention and may be subject to change by skilled persons within the scope of the invention without departing from the concept thereof.

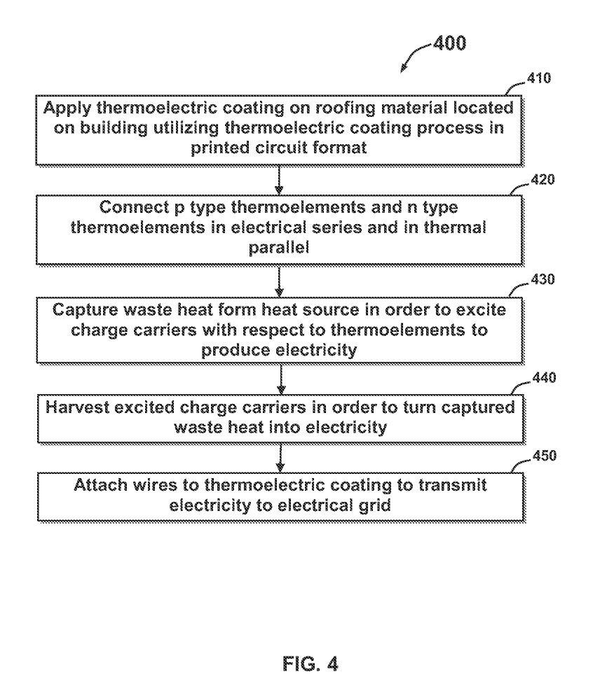

FIG. 4 illustrates a high level flow chart of operation illustrating logical operational steps of a method 400 for generating electricity utilizing the thermometric apparatus 100, in accordance with the disclosed embodiments. The thermoelectric coating 130 can be applied to the roofing material 150 utilizing the thermoelectric coating process in, for example, a printed circuit format, as illustrated at block 410. The p type thermo elements 165 and the n type thermo elements 160 associated with the thermoelectric generation unit 100 can be connected in series and in thermal parallel, as depicted at block 420. Waste heat can be captured from the heat source 110 in order to excite the charge carriers associated with the thermoelements 160 and 165, as indicated at block 430. It can be appreciated that such waste heat is typically a result of the exposure of roofing material to the sun (e.g., roofing shingles located on a building). The excited charge carriers can be harvested in order to turn the waste heat captured from the heat source 110 into electricity, as illustrated at block 440. The electrical conductors can be attached to the thermoelectric coating 130 to transmit generated electricity to the electrical grid 180, as indicated at block 450.

It will be appreciated that variations of the above-disclosed and other features and functions, or alternatives thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A thermoelectric roofing apparatus, comprising:
a thermoelectric coating applied to a heat exchanger material via a thermoelectric coating process to capture waste heat from a heat source and generate electrical energy, said heat exchanger material located on a building; and
a plurality of electrical conductors attached to said thermoelectric coating to transmit said electrical energy generated as a byproduct of heat exchange.

2. The apparatus of claim 1 wherein said thermoelectric coating comprises a semiconductor material.

3. The apparatus of claim 1 further comprising a plurality of n-type thermoelectric coating and a plurality of p-type thermoelectric coating connected in electrical series and in thermal parallel.

4. The apparatus of claim 3 further comprising at least one charge carrier with respect to said n-type thermoelectric coating is excited when said heat flows through said heat exchanger material in order to generate said electrical energy.

5. The apparatus of claim 1 wherein said semiconductor material is applied to said heat exchanger material in a printed circuit format.

6. The apparatus of claim 1 wherein said thermoelectric coating process comprises a spray-on thermoelectric coating process.

7. The apparatus of claim 1 wherein said heat exchanger material comprises a roofing material.

8. The apparatus of claim 1 wherein said heat exchanger material comprises a shingle.

9. A thermoelectric roofing apparatus, comprising:
a thermoelectric coating applied to a heat exchanger material via a thermoelectric coating process to capture waste heat from a heat source and generate electrical energy, said heat exchanger material located on a budding, wherein said heat exchanger material comprises a roofing material; and
a plurality of electrical conductors attached to said thermoelectric coating to transmit said electrical energy generated as a byproduct of heat exchange.

10. The apparatus of claim 9 wherein said thermoelectric coating comprises a semiconductor material.

11. The apparatus of claim 9 further comprising a plurality of n-type thermoelectric coating and a plurality of p-type thermoelectric coating connected in electrical series and in thermal parallel.

12. The apparatus of claim 11 further comprising at least one charge carrier with respect to said n-type thermoelectric coating is excited when said heat flows through said heat exchanger material in order to generate said electrical energy.

13. The apparatus of claim 9 wherein said semiconductor material is applied to said heat exchanger material in a printed circuit format.

14. The apparatus of claim 10 wherein said thermoelectric coating process comprises a spray-on thermoelectric coating process.

15. The apparatus of claim 10 wherein said roofing material comprises at least one shingle.

16. The apparatus of claim 9 wherein said roofing material comprises a plurality of shingles.

17. A method of configuring a thermoelectric roofing apparatus, comprising:
applying a thermoelectric coating to a heat exchanger material via a thermoelectric coating process to capture waste heat from a heat source and generate electrical energy, said heat exchanger material located on a building; and
attaching a plurality of electrical conductors to said thermoelectric coating to transmit said electrical energy generated as a byproduct of heat exchange.

18. The method of claim 17 further comprising configuring said thermoelectric coating to comprise a semiconductor material.

19. The method of claim 17 further comprising connecting a plurality of n-type thermoelectric coating and a plurality of p-type thermoelectric coatings in electrical series and in thermal parallel.

20. The method of claim 17 further comprising applying said semiconductor material to said heat exchanger material in a printed circuit format.

21. The method of claim 17 wherein said thermoelectric coating process comprises a spray-on thermoelectric-coating process.

22. The method of claim 17 wherein said heat exchanger material comprises a roofing material.
